(19) United States
(12) Patent Application Publication
(10) Pub. No.: US 2026/0101721 A1
(43) Pub. Date: Apr. 9, 2026

(54) CAUSALITY-BASED FEATURE LEARNING FOR ON-TOOL PROCESS MONITORING AND TOOL CONTROL

(71) Applicant: Applied Materials, Inc., Santa Clara, CA (US)

(72) Inventor: SIDHARTH BHATIA, Santa Cruz, CA (US)

(21) Appl. No.: 18/908,572

(22) Filed: Oct. 7, 2024

(51) Int. Cl. H01L 21/66

(52) U.S. Cl. CPC H10P 74/203

(57) ABSTRACT

Embodiments described herein relate to a method that includes obtaining a set of spectral data and a set of critical dimension (CD) data from a plurality of substrates, and extracting a spectral feature from the set of spectral data and a CD feature from the set of CD data with a feature extraction process. In an embodiment, the method further comprises implementing a first radial basis decomposition process on the spectral feature and a second radial basis decomposition process on the CD feature to develop a spectral radial basis decomposition coefficient and CD radial basis decomposition coefficient, and identifying a causal relationship between the spectral radial basis decomposition coefficient and the CD radial basis decomposition coefficient based on a temporal trend.

### BACKGROUND

### 1) Field

Embodiments of the present disclosure pertain to the field of causality-based feature learning for tool control and virtual metrology, including virtual metrology.

### 2) Description Of Related Art

Semiconductor processing relies on the precise control of many different processing conditions in order to produce high yielding devices. As the size of individual structures are reduced, the demands for process control continue to increase. In order to monitor processing outcomes, spectral metrology (e.g., infrared (IR) reflectometry, ellipsometry, etc.) may be used. Ideally, the data obtained from the spectral metrology is correlated with data relating to the structure of devices on the wafer (such as critical dimension (CD), line and space (L/S) measurements, or the like). Existing solutions to determine such correlations are based on extensive experimentation through the design and execution of detailed design of experiments (DOEs).

However, relying on such investigative techniques leads to several issues. For example, the resulting correlations and models may not be as robust as desired.

Particularly, such solutions often lack one or more of external validity, temporal validity, ecological validity, or population validity. Accordingly, the resulting models and control algorithms are not suitable for long term deployment over a fleet of multiple processing tools.

### SUMMARY

Embodiments described herein relate to a method that includes obtaining a set of spectral data and a set of critical dimension (CD) data from a plurality of substrates, and extracting a spectral feature from the set of spectral data and a CD feature from the set of CD data with a feature extraction process. In an embodiment, the method further comprises implementing a first radial basis decomposition process on the spectral feature and a second radial basis decomposition process on the CD feature to develop a spectral radial basis decomposition coefficient and CD radial basis decomposition coefficient, and identifying a causal relationship between the spectral radial basis decomposition coefficient and the CD radial basis decomposition coefficient based on a temporal trend.

Embodiments described herein relate to a method that includes identifying a causal relationship between a spectral radial basis decomposition coefficient and a critical dimension (CD) radial basis decomposition coefficient, where the causal relationship includes an association between a first temporal trend of the spectral radial basis decomposition coefficient and a second temporal trend of the CD radial basis decomposition coefficient, where the causal relationship is generated through a machine learning process that is applied to a spectral data set and a CD data set that are obtained from a plurality of substrates. In an embodiment, the method further includes setting an upper threshold and a lower threshold for the spectral radial basis decomposition coefficient that corresponds to acceptable CD values, and monitoring spectral radial basis decomposition coefficient outputs of subsequently processed substrates. In an embodiment, the method further includes identifying one or more subsequently processed substrates with a spectral radial basis decomposition coefficient output that is outside of the upper threshold and the lower threshold as a non-conforming substrate.

Embodiments described herein relate to a method that includes obtaining a set of spectral data and a set of critical dimension (CD) data from a plurality of substrates, and extracting a spectral feature from the set of spectral data with a first feature extraction process and a CD feature from the set of CD data with a second feature extraction process. In an embodiment, the method further includes implementing a first radial basis decomposition process on the spectral feature and a second radial basis decomposition process on the CD feature to develop a spectral radial basis decomposition coefficient and a CD radial basis decomposition coefficient, and identifying a causal association between the spectral radial basis decomposition coefficient and the CD radial basis decomposition coefficient. In an embodiment, the method further includes affirming the causal association as a causal effect between the spectral radial basis decomposition coefficient and the CD radial basis decomposition coefficient through physical experimentation and/or observational data, and identifying a causal relationship between the spectral radial basis decomposition coefficient and a control knob of a chamber, where the causal relationship includes a relationship between a temporal trend of the spectral radial basis decomposition coefficient and a temporal trend of the control knob. In an embodiment, the method further includes developing and/or modifying a control loop for processing substrates in the chamber based on the causal relationship between the spectral radial basis decomposition coefficient and the control knob.

### BRIEF DESCRIPTION OF THE DRAWINGS

FIG. 1 is a flow diagram of a methodology for functional mapping of metrology features to critical dimension (CD) features that includes temporal, ecological, and population validity, in accordance with an embodiment.

FIG. 2 is a flow diagram of a methodology for generating metrology temporal trends, in accordance with an embodiment.

FIG. 3 is a flow diagram of a methodology for generating causal associations between metrology data, CD data, and sensor data, in accordance with an embodiment.

FIG. 4 is a flow diagram of a methodology for generating causal associations between the processing data and metrology data in order to implement improved tool control, in accordance with an embodiment.

FIG. 5A is a graph that illustrates long period drift results for a plurality of chambers, in accordance with an embodiment.

FIG. 5B is an illustration depicting the validation of causal relationships between metrology data and CD data, in accordance with an embodiment.

FIG. 5C is a graph illustrating control loop improvements, in accordance with an embodiment.

FIG. 5D is a schematic of a control loop based on causal relationships for improved tool control, in accordance with an embodiment.

FIG. 6 is a flow diagram of a process for creating causal associations between spectral metrology data and CD data, in accordance with an embodiment.

FIG. 7 is a flow diagram of a process for implementing virtual metrology based on causal associations between spectral metrology data and CD data, in accordance with an additional embodiment.

FIG. 8 is a flow diagram of a process for improving a process control loop based on causal associations between spectral metrology data and CD data obtained through machine learning processes, in accordance with an embodiment.

FIG. 9 is a schematic illustration of a processing tool with a chamber, a metrology unit, and a controller for implementing improved processing outcomes within the processing tool, in accordance with an embodiment.

FIG. 10 illustrates a block diagram of an exemplary computer system of a processing tool, in accordance with an embodiment of the present disclosure.

### DETAILED DESCRIPTION

Causality-based feature learning systems and modules for tool control and virtual metrology are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, existing solutions for determining associations between spectral metrology data (e.g., infrared (IR) reflectometry, ellipsometry, etc.) and device feature data (e.g., critical dimension (CD), line/space (L/S), etc.) relies on extensive physical experimentation. In addition to the time and expense of such experimentation, the resulting models lack external validity (such as ecological validity, temporal validity, or population validity). Ecological validity may generally refer to the applicability of the model to systems and tools outside of the testing environment. Temporal validity may refer to the applicability of the model over longer periods of time. For example, processing conditions tend to drift in semiconductor processing environments, which may make the model less accurate over time. Population validity may refer to the applicability of the model to larger populations. For example, applicability of the model to different semiconductor processing tools within a facility may be a measure of population validity in some embodiments.

Accordingly, embodiments disclosed herein include a methodology for developing causal associations between the spectral metrology and the device feature data that exhibit external validity. This can provide several benefits for the control of semiconductor processing across many different chambers within a facility and over long periods of time (e.g., to account for drift in the various chambers). For example, the causal associations allow for the implementation of virtual metrology and/or virtual sensing. That is, spectral metrology measurements can be processed in real time to determine if a processed substrate has CD values within specification. Stated differently, when the spectral metrology data of a processed substrate falls outside of a designated threshold, the processed substrate can be identified as a non-conforming substrate. This can trigger the need for additional metrology on the non-conforming substrate and/or trigger an investigation into the chamber used to process the non-conforming substrate in order to see if the chamber needs maintenance and/or make adjustments to one or more control knobs of the processing environment.

Additionally, the causal associations may be used to tune and/or develop accurate control loops for processing substrates through the plurality of chambers within the facility. These control loops may also exhibit external validity, including ecological validity, temporal validity, and population validity. As such, the resulting control loop models provide more accurate long term control of the plurality of chambers in the facility. For example, the improved control loops allow for the identification of causal associations between different data sets and/or control knob settings (e.g., hardware configuration control knobs, process recipe control knobs, etc.).

More generally, the methodology may include a multiple tier methodology that builds on itself in order to provide different levels of control within a semiconductor processing environment. In a first tier, causal associations are developed through a long period drift association analysis across multiple chambers. Generally, features from spectral data sets and CD data sets may be extracted, and a radial basis decomposition process can be used to generate radial basis functions (or vectors) and respective coefficients (or eigen values) whose temporal distributions allow for the generation of the causal associations between the spectral data and CD data. For example, one or more causal discovery algorithms may be used to identify the causal relationships within the spectral data and the CD data. For example, one or more of a causal additive model (CAM) algorithm, a Greedy equivalence search (GES) algorithm, a fast causal inference (FCI) algorithm, an inductive causation (IC) algorithm, a NOTEARS algorithm, a LiNGAM algorithm, an interventional distribution adjustment (IDA) algorithm, a structural hamming distance (SHD) algorithm, a max-min hill-climbing (MMHC) algorithm, fa ast GES (FGES) algorithm, a PC-MCI algorithm, an additive noise model (ANM) algorithm, a Bayesian network learning (BNL) algorithm, a causal graphical neural network (CGNN) algorithm, a TETRAD algorithm, a DirectLiNGAM algorithm, a joint causal inference (JCI) algorithm, an information geometric causal inference (IGCI) algorithm, or the like may be used to identify causal relationships in the between the spectral data and the CD data. In some embodiments, a causal direction may be assigned to each causal link generated by the causal discovery algorithm. In some embodiments, the use of radial basis functions limits overfitting of data sets and helps denoise the data sets.

With respect to the first tier, the long period may be a day or more, five days or more, or ten days or more. This extended analysis period allows for the generation of causal associations that exhibits temporal validity. For example, the long period allows for drift within the different chambers to occur, and the effects of the drift can be capture by the causal associations. Chamber drift may refer to the gradual change of processing outcomes due to changes within the processing conditions, processing configurations, and/or the like. As an example, wear of different components within the chamber over time may result in chamber drift. The monitoring of multiple chambers enables the generation of a control model that exhibits ecological and/or population validity.

A second tier may include validation of the causal associations between data sets through physical experimental. The second tier may include A-B testing, sensitivity testing, and/or the like in order to confirm the validity of causal associations determined in the first tier. At this point the resulting causal associations can be used to implement virtual metrology and/or virtual sensing during the subsequent processing of substrates. The confirmed causal associations allow for radial basis vectors that are developed in the first tier to be used in order to more efficiently track outputs from spectral metrology that can be directly related to device feature data. This allows for the rapid classification of processed substrates into those that conform to desired specifications and those that are non-conforming (i.e., which fall outside of predetermined thresholds). The identification of a non-conforming substrate may trigger further metrology investigation of such substrates and/or an investigation of the chamber that processed the non-conforming substrate (e.g., to see if maintenance is needed).

In an embodiment, a third tier may include further physical experimental validation in order to generate causal associations between the spectral metrology and one or more control knobs (e.g., hardware control knobs and/or process recipe control knobs). As such, changes to one or more control knobs during processing will produce changes to the resulting spectral metrology results with a high degree of accuracy. In some instances, this type of process may sometimes be referred to as a “do-operator” in the field of causal inference. These associations can be used to build and/or refine control loop models with high accuracy. In some instances, this optimization process may be implemented manually or through an automated process. Upon proper optimization, the control loop model may be deployed in a facility to improve the performance of a plurality of processing chambers over time.

In embodiments described in greater detail herein, the control loop model is deployed in a semiconductor processing environment. For example, the control loop may be used to control the performance of semiconductor processing chambers, such as etching chambers, deposition chambers, annealing chambers, or the like. Though, it is to be appreciated that the methodologies described herein may also be applicable to other manufacturing environments. For example, manufacturing environments where causal associations between data sets that are not readily apparent may be improved through the use of a control loop model that has been optimized through the development of causal associations between processing results, metrology results, sensor data, and/or the like using machine learning processes and/or techniques, such as those described in greater detail herein.

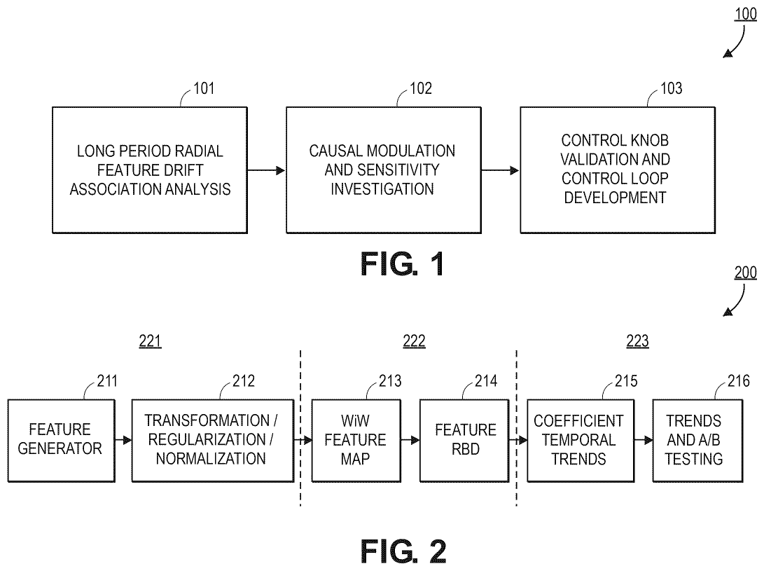

Referring now to FIG. 1, a process flow diagram of a multi-tier methodology 100 to generate and use causal associations between data sets in a manufacturing process is shown, in accordance with an embodiment. In a particular embodiment, the manufacturing process is a semiconductor manufacturing process that includes a processing chamber, such as a plasma chamber. For example, the chambers may be used for an etching process, a deposition process, an annealing process, or the like. As will be described in greater detail herein, the control system may be suitable for controlling a plurality of chambers.

In an embodiment, the methodology may begin with a first tier 101, which comprises implementing a long period radial feature drift association analysis. The first tier 101 may be a process that is implemented on a plurality of chambers. Tracking and drawing causal associations between data sets from substrates processed on multiple chambers allows for the resulting causal associations to exhibit external validity, such as population validity and/or ecological validity.

In an embodiment, the causal associations are also developed over a period of time. In some embodiments, the period of time may include a day or longer, three or more days, or five or more days. The longer duration of the analysis captures variations in the systems that drive process drift. Accordingly, the resulting causal associations more accurately account for chamber drift. This allows for the causal associations to exhibit improved temporal validity as well.

In an embodiment, the radial feature drift association analysis relies on the generation of radial basis decomposition coefficients (or vectors) from at least two different sets of data obtained from processed substrates. A first set of data may include spectral metrology data, such as IR reflectometry data or ellipsometry data. A second set of data may include device feature data, such as CD, L/S, or the like. Large spectral data sets and CD data sets may undergo a feature extraction process typical of machine learning and/or artificial intelligence processes in order to produce spectral features and CD features. For example, the feature extraction may use one or more of a singular value decomposition (SVD) process, an independent component analysis (ICA) process, a principal component analysis (PCA) process, a Fourier transform, a wavelet transform, a power spectral density, an autoencoder, a singular spectral analysis, filter banks, or the like.

After the features from each data set are obtained, a radial decomposition process may be used in order to develop spectral radial basis decomposition coefficients and CD radial basis decomposition coefficients. In an embodiment, the radial decomposition may include any suitable functions, such as Zernike functions, Bessel functions, spherical harmonics, aspheric polynomials or an orthogonal function on a unit disk, such as Legendre, Legendre-Fourier, Chebyshev, Laguerre, Jacobi, or the like. The generation of spectral radial basis decomposition coefficients and CD radial basis decomposition coefficients allows for the learning of causal associations and dependencies that are based on temporal trends of the spectral and CD radial basis decomposition coefficients. In some embodiments, such causal associations and dependencies prevent overfitting and helps to reduce noise in the data sets. As such, analysis of the data sets in view of the radial basis decomposition coefficients allows for improved causal association generation based on the data sets obtained over the long period monitoring.

In an embodiment, the methodology 100 may continue with a second tier 102, which comprises implementing a causal modulation and sensitivity investigation. In an embodiment, the second tier 102 may include validation of the causal associations obtained in the first tier 101 through physical experimental. For example, testing (e.g., randomized controlled experimentation (RCE), A-B testing, etc.) can be used in order to take the causal associations to causal dependencies or causal effects. Experimental validation may also allow for the identification of causal effects between control knobs (e.g., hardware control knobs and/or process recipe control knobs) and the processing outcomes. Control knobs may include any of the parameters of the processing chamber and/or processing recipe that can be modulated in order to alter the processing outcome. For example, control knobs may include RF power settings, flow ratio controller (FRC) settings, electrostatic chuck (ESC) temperature, or the like. Control knobs that may be considered hardware configurations may include component positioning, component selection, component material, or the like.

After the causal effects are confirmed, embodiments may use those causal effects in order to monitor subsequent processing of substrates in the plurality of chambers. For example, virtual metrology and/or virtual sensing may be implemented in order to monitor the quality of the subsequently processed substrates. In the case of virtual metrology, subsequently obtained spectral data (e.g., IR reflectometry data or ellipsometry data) can be used as an input and the corresponding CD data can be inferred through the known associations between the data sets. Accordingly, time consuming measurements of the CD data can be bypassed in order to check the quality of the processing. When the spectral data obtained for a substrate is within a desired threshold (i.e., between an upper limit and a lower limit), the substrate may be verified as being within specification. In contrast, when the spectral data obtained for a substrate is outside of the desired threshold, the substrate may be identified as non-conforming. This may indicate additional metrology is needed and/or the chamber needs to be inspected.

In an embodiment, the methodology 100 may continue with a third tier 103, which comprises implementing a control knob validation and developing and/or refining a control loop model. Control knob validation may include additional experimental validation in order to confirm causal effects between one or more control knobs (e.g., hardware control knobs and/or process recipe control knobs) and the spectral radial basis decomposition coefficients. The experimental validation may include sensitivity testing and/or mapping of outcomes. In an embodiment, the development and/or refinement of the control loop may include the use of manual and/or automated tuning of one or more of the processing chambers. The combination of experimental validation with manual (and/or automated) input may be used in order to improve the process capability index (Cpk) of the controlled systems. For example, the overall process uniformity over a period of time may be improved.

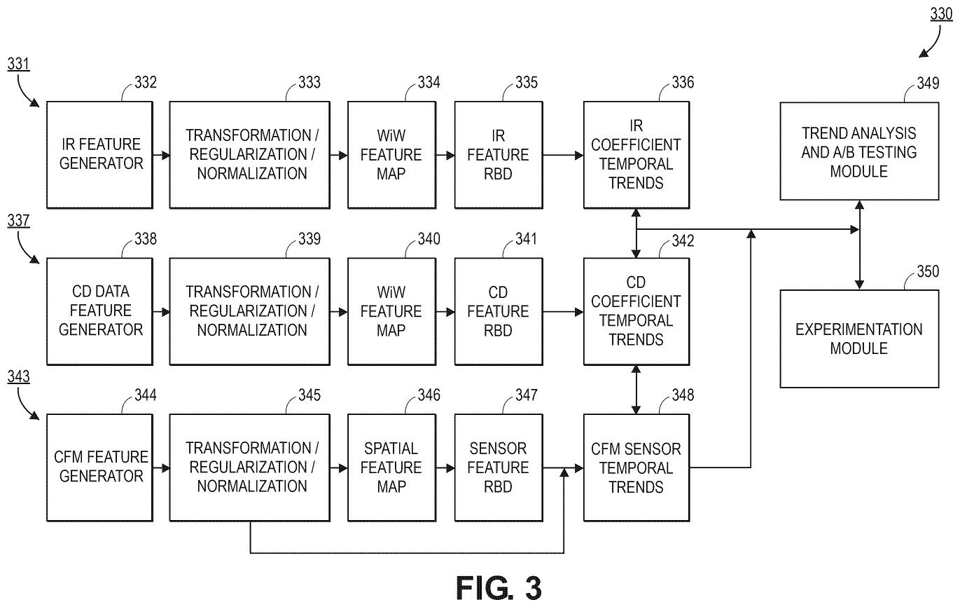

Referring now to FIG. 2, a flow diagram of a process 200 for generating spectral radial basis decomposition coefficients and causally associating spectral radial basis decomposition coefficients with CD radial basis decomposition coefficients is shown, in accordance with an embodiment. The process 200 may be broken into three phases 221, 222, and 223. Though, it is to be appreciated that the use of different phases 221-223 is not necessary, and the entire process 200 may be considered as being a single process. In the particular embodiment described in FIG. 2, the data set includes spectral data such as IR reflectometry measurements. Though, as will be described in greater detail herein, other data sets may be similarly manipulated for generation of other types of radial features.

In an embodiment, the process 200 may being with operation 211, which comprises generating features from a data set. The data set may include a spectral data set that is obtained from a plurality of substrates that are processed in a plurality of chambers over a period of time. The period of time may be one or more days, three or more days, or five or more days. In an embodiment, the spectral features may be extracted from the spectral data set with a feature extraction process or other feature engineering process, such as an ICA process, a PCA process, an SVD process, Fourier transforms, wavelet transforms, power spectral density, autoencoders, singular spectral analysis, filter banks or the like. As used herein, a feature may refer to an individual measurable property within a recorded dataset. For example, in the case of IR reflectometry, a metrology feature may be a reflectance spectra, a portion of a reflectance spectra, or the like. In an embodiment, the process 200 may continue with operation 212, which comprises refining the extracted spectral features through one or more of transformation processes, regularization processes, and/or normalization processes.

In an embodiment, the process 200 may now continue into the second phase 222. In an embodiment, operation 213 may include the generation of a wafer feature map, such as a within wafer (WiW) feature map. WiW may be used to map the values of different measured features onto the wafer (or other substrate). In an embodiment, the process 200 may continue with operation 214, which may comprise implementing a radial basis decomposition process on the spectral features. The radial basis decomposition process may result in the generation of spectral radial basis decomposition coefficients (or vectors). The spectral radial basis decomposition coefficients may be used to project the features into a higher dimensional space that is more easy to manipulate to find causal associations and dependencies. This allows for more effective identification of patterns, trends, and/or relationships within the larger data sets. Radial basis decomposition may also allow for denoising of the dataset and/or reducing the risk of overfitting the dataset. The radial features may be referred to as being orthogonal to each other. In an embodiment, the radial basis decomposition may use any suitable radial basis functions that are typical of machine learning processes. For example, Zernike functions, Bessel functions, spherical harmonics, aspheric polynomials or an orthogonal function on a unit disk, such as Legendre, Legendre-Fourier, Chebyshev, Laguerre, Jacobi, and/or the like may be used as the radial basis functions.

In an embodiment, the process 200 may continue into the third phase 223, which comprises operation 215. In an embodiment, operation 215 may include the generation and/or identification of temporal trends of the non-zero radial basis decomposition coefficients from the data set. In an embodiment, the temporal trends may be generated through a process that monitors the extracted features and/or the radial functions over a period of time. For example, the period of time may be a day or more, three or more days, or five or more days. This allows for the monitored data to be used in the formation of a control model that exhibits temporal validity. In an embodiment, the monitoring may include analyzing coefficients of the temporal trends as they change over time by using causal discovery and association algorithms, such as any of the causal discovery and/or association algorithms described in greater detail herein. In this wave, causal associations (which may be stronger than correlations, but weaker than cause-effect relationships) may be determined.

In an embodiment, the process 200 may continue with operation 216, which comprises developing a display method for trends and/or the execution of further testing. For example, drift analysis (e.g., to see how chambers react over time, or the like) may be done to further reinforce the temporal validity of the control model. Other testing, such as RCE, A-B testing, do-operator experiments, or the like may be implemented in operation 216. Additionally, display options, such as databases, dashboards, and/or the like may be generated in order to more clearly visualize the dataset. In an embodiment, the testing may allow for the conversion of causal associations into causal effects and/or causal relationships. The testing may also allow for the identification of sensitivities of process and/or hardware knobs in relation to spectral radial basis decomposition coefficients. As such, the confirmed and validated causal relationship may be used in order to develop and/or run a control loop model to operate processing tools.

More generally, the operations in FIG. 2 may have the following process flow: 1) generation of spectral data and CD data; 2) feature extraction from the spectral data and CD data sets in order to form WiW feature plots; 3) radial basis decomposition of the spectral data and the CD data to form radial basis decomposition coefficients (or vectors); 4) tracking temporal trends of non-zero radial basis decomposition coefficients; 5) identifying causal associations using one or more causal discovery algorithms with respect to the temporal trend data of radial basis decomposition coefficients for the spectral data and the CD data; 6) implementing further experimentation in order to convert causal associations to causal effects and/or causal relationships and learning sensitivities of process and/or hardware know with respect to spectral radial basis decomposition coefficients; and 7) using the confirmed and/or validated causal relationships in order to develop and/or run control loops for running one or more processing tools. In an embodiment, the processes 1-7 may all be practiced together, or one or more of the processes 1-7 may be used in order to implement different portions of the overall methodology.

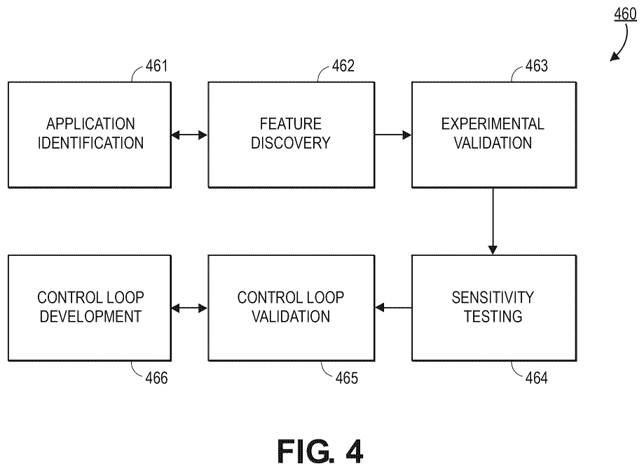

Referring now to FIG. 3, a flow diagram of a process 330 for generating temporal trends based on radial features for a plurality of different datasets is shown, in accordance with an embodiment. The process 330 may include a plurality of tracks. For example, tracks 331, 337, and 343 are shown in FIG. 3. The different datasets in each track 331, 337, or 343 may correspond with different types of data that is obtained during the processing of wafers (or other substrates) in a plurality of chambers. For example, the first track 331 may correspond to spectral metrology data, such as IR reflectometry data, the second track 337 may correspond to CD data (or other processing result data, such as yield data, key performance indicator (KPI) data, and/or the like), and the third track 343 may correspond to sensor data (such as data from sensors incorporated into the plurality of chambers).

In an embodiment, the tracks 331, 337, and 343 may be run substantially in parallel until the data is combined during the trend analysis operation 349 and experimentation module operation 350. The first track 331 may be similar to the process 200 described in greater detail above. For example, at operation 332 IR features may be generated through any suitable process, such as ICA, PCA, and/or SVD. While IR reflectometry features are described herein, it is to be appreciated that any other type of spectral metrology data (e.g., ellipsometry) may be used in accordance with other embodiments or multiple different types of spectral metrology data may be used.

Thereafter, the features may be modified (e.g., through transformation, regularization, normalization, or the like) in operation 333. The WiW feature map may be generated in operation 334, and radial basis decomposition of the IR features may be implemented in order to generate IR radial features in operation 335. IR coefficients and temporal trends may be identified in operation 336.

A similar process may be used for the second track 337 where metrology data is utilized. As used herein, the metrology data is referred to as CD data. Though, it is to be appreciated that any suitable type of processing outcome data (e.g., yield data, KPI data, etc.) may be used in other embodiments. Operations 339, 340, 341, and 342 may be similar to operations 333, 334, 335, and 336 described above, with the exception being the dataset that is being manipulated.

In an embodiment, the third track 343 may begin with obtaining timeseries data from sensors deployed in the plurality of chambers at operation 344. Thereafter, the operation 345 may include a feature generation process, similar to operations 332 and/or 338 described above. A spatial sensor map may be generated in operation 346, and sensor feature radial basis decomposition to generate sensor radial features is done in operation 347. In an embodiment, sensor temporal trends can be determined in operation 348.

At the end of each of the tracks 331, 337, and 343, data can be shared between tracks and delivered for trend analysis at operation 349. The trend analysis may include temporal association analysis, temporal causal analysis, and/or the like. That is, causal relationships between two or more of the different types of radial features can be determined at operation 349. In an embodiment, operation 349 may also include a causal associations discovery module, A-B testing, dashboarding, database generation, and/or the like.

In an embodiment, the process 330 may then continue with operation 350 which may include the use of one or more experimental modules. In an embodiment, the experimental modules may be used to identify hardware knobs and/or hardware configurations that correspond to the radial basis decomposition coefficients (or radial basis vectors). The experimentation may also include the identification of processing knobs that correspond to radial basis decomposition coefficients (or radial basis vectors). Drift monitoring for sensors and/or radial basis coefficients may also be implemented during operation 350.

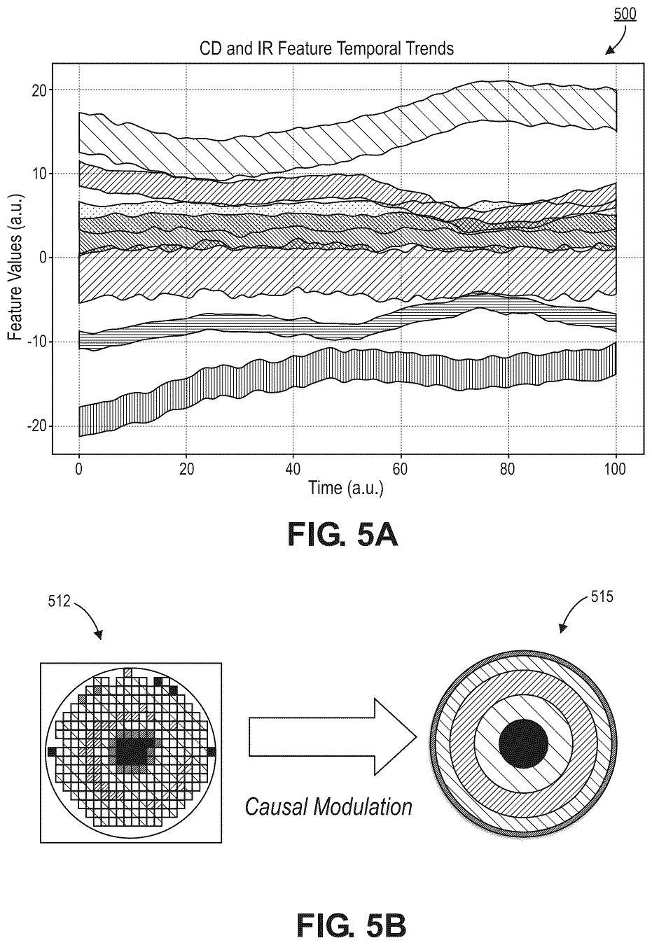

Referring now to FIG. 4, a flow diagram of a process 460 for developing a control loop for semiconductor processing is shown, in accordance with an embodiment. In an embodiment, the process 460 may be used in order to generate causal associations and dependencies between processing data and metrology data in order to provide a more robust control loop model that exhibits external validity (e.g., temporal validity, ecological validity, population validity, and/or the like).

In an embodiment, the process 460 begins with operation 461, which comprises identifying a targeted application for control. For example, the application may be an etching application, a deposition application, a treatment application, or the like. The application identification process may further include more detailed issues, such as processing result uniformity (e.g., etch rate, deposition rate, etc.), CD issues, L/S issues, KPI issues, drift concerns with any of the issues, and/or the like.

In an embodiment, the process 460 may then continue with a feature discovery operation 462. In an embodiment, the feature discovery operation 462 may include processes similar to any of those described above with respect to those described in FIGS. 2 and 3. For example, spectral metrology features (e.g., IR reflectometry, ellipsometry, etc.) and CD features may be extracted from relevant data sets that map a process over a period of time (e.g., one or more days, three or more days, five or more days, etc.). The spectral metrology features and the CD features may be decomposed with a radial basis decomposition process in order to generate spectral radial decomposition coefficients and CD radial basis decomposition coefficients. The monitoring can be implemented across a plurality of chambers as well. The long duration (in order to capture drift) and the plurality of chambers being monitored (to capture a larger population) allows for the resulting control loop to exhibit improved external validity. In an embodiment, the use of radial features allows for easier identification of causal associations, dependencies and effects between the metrology radial features and the CD radial features.

In an embodiment, the process 460 may continue to operation 463, which comprises implementing experimental validation. In an embodiment, the experimental validation allows for the confirmation of the causal relationships between spectral metrology functions and the CD radial basis functions. The experimental validation may include the design and execution of an RCE, a DOE, do-operator experiments, or the like. Though, the RCE, DOE, or do-operator experiments may be significantly less extensive compared to solutions where correlations are mapped entirely by DOE as is presently done.

In an embodiment, the process 460 may continue with operation 464, which comprises the implementation of sensitivity testing. In an embodiment, the sensitivity testing may be used in order to determine control knobs (e.g., hardware settings and/or configurations, process settings, etc.) that have causal effects on the metrology radial features. For example, the control knobs may include one or more of RF power, FRC ratios, ESC temperatures, component dimensions, component materials, component positionings, and/or the like.

In an embodiment, the process 460 may continue with operation 465, which comprises validating a control loop. In an embodiment, the control loop may be a manual and/or open loop control that allows for modifying one or more control knob settings to verify that changes to the control knobs drive the desired changes. In an embodiment, the operation can also be used to verify that the desired improvements to Cpk and/or other processing results have been obtained.

In an embodiment, the process 460 may continue with operation 466, which comprises further development of the control loop. The development of the control loop may leverage the long term and causally dependent or causally connected metrology radial basis decomposition coefficients and control knob relationships in order to improve the overall performance of the control loop. In an embodiment the developed control loop may be a run-to-run (R2R) control loop and/or a lot-to-lot (L2L) control loop in order to improve performance over time and minimize the effects of drift.

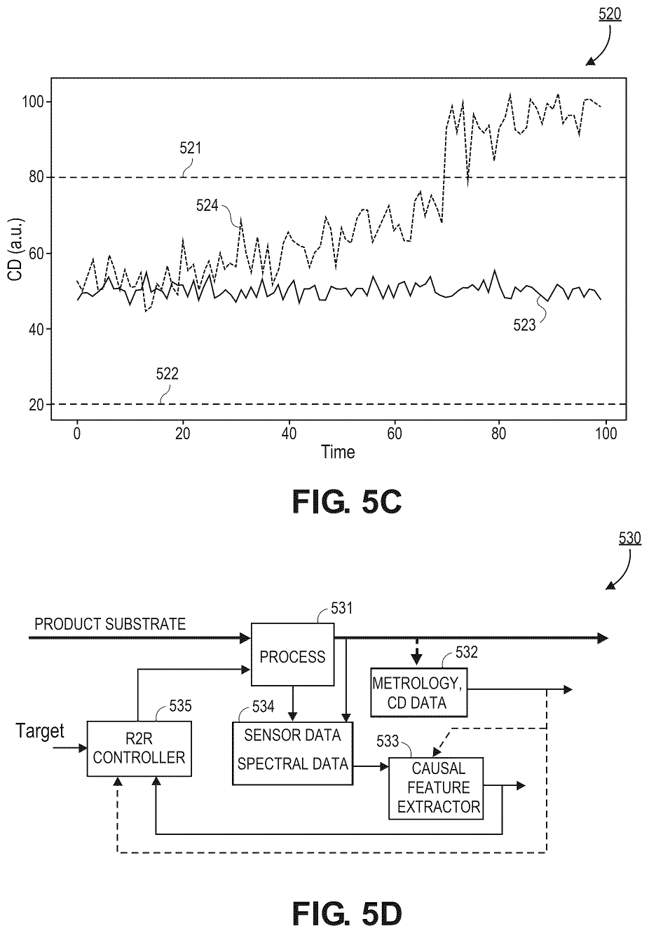

Referring now to FIG. 5A-5D, illustrations depicting graphs, maps, and/or diagrams that may be useful for different operations of the process 460 are shown, in accordance with various embodiments. FIG. 5A is a plot 500 that depicts the long period temporal trend of a plurality of metrology features. For example, the number of metrology features that may be monitored can be ten or more, thirty or more, or fifty or more. In an embodiment, a band for each metrology feature is shown instead of the specific data point. The band may represent the confidence interval of each of the metrology feature measurements.

FIG. 5B is a pair of maps visually identifying the CD radial basis function (or the CD radial basis vector) 512 and the spectral metrology radial basis function (or the spectral metrology radial basis vector) 515. The maps are used to represent the verification of the causal relationship between the two vectors as a result of the experimental validation in operation 463. For example, the experimental validation may include the implementation of do-operator experiments, RCEs, or DOEs.

FIG. 5C is a graph 520 that illustrates the manual control loop validation in operation 464. The lines 521 and 522 may be boundary lines for keeping a process within a desired specification. The line 524 may represent an uncontrolled process that strays outside of the desired processing boundary, and the line 523 may represent a process that is controlled with process and/or hardware control knobs that have been associated with radial features earlier in the process flow.

FIG. 5D is a diagram of a control loop 530 that can be used to keep the processing within the desired specifications over time. The control loop 530 may include a process block 531. Selected ones of the substrates that are processed in the process block 531 can be diverted for metrology at block 532. Additionally, data 534 (e.g., sensor data, spectral data, metrology data, CD data, etc.) from the process block 531 can be sent to a causal feature extraction block 533. Radial basis decomposition can be implemented to generate radial features that can be used to develop causal associations. The resulting associations and radial features may be fed to a controller 535, such as an R2R controller and/or a L2L controller. The controller 535 can use the incoming data to generate a control effort that is fed back to the process block 531 in order to bring the process back into specification and/or to maintain a target process specification.

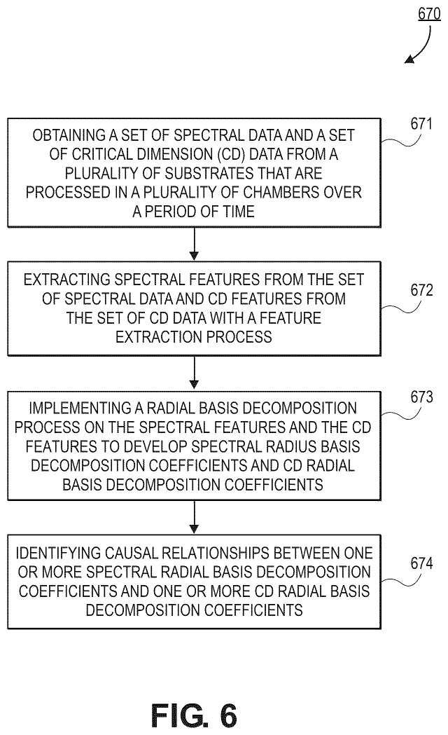

Referring now to FIG. 6, a flow diagram of a process 670 for identifying causal associations between spectral data and CD data in processed substrates is shown, in accordance with an embodiment. In an embodiment, the process 670 may begin with operation 671, which comprises obtaining a set of spectral data and a set of CD data from a plurality of substrates that are processed in a plurality of chambers over a period of time. In an embodiment, the spectral data comprises any suitable type of spectral metrology measurement, such as IR reflectometry data or ellipsometry data. In an embodiment, the period of time may be one or more days, three or more days, or five or more days.

In an embodiment, the process 670 may continue with operation 672, which comprises extracting spectral features from the set of spectral data and CD features from the set of CD data with a feature extraction process. In an embodiment, the feature extraction process comprises one or more of a SVD process, an ICA process, a PCA process, Fourier transforms, wavelet transforms, power spectral density, autoencoders, singular spectral analysis, filter banks, or the like. In an embodiment, one or both of the spectral features or the CD features are modified through one or more of a transformation process, a regularization process, or a normalization process. In an embodiment, one or both of the spectral features and the CD features are used to build a within wafer feature map for each of the substrates processed in the plurality of chambers.

In an embodiment, the process 670 may continue with operation 673, which comprises implementing a radial basis decomposition process on the spectral features and the CD features to develop spectral radial basis functions and CD radial basis functions. In an embodiment, the radial basis decomposition process comprises the use of one or more of a Zernike function, a Bessel function, spherical harmonics, aspheric polynomials or an orthogonal function on a unit disk, such as Legendre, Legendre-Fourier, Chebyshev, Laguerre, Jacobi, or the like.

In an embodiment, the process 670 may continue with operation 674, which comprises identifying causal associations between one or more spectral radial basis decomposition coefficients and one or more CD radial basis decomposition coefficients. For example, the causal relationships (or causal dependencies) between the one or more spectral radial basis decomposition coefficients and the one or more CD radial basis decomposition coefficients may be validated to generate causal effects through physical experimentation (e.g., a do-operation), such as a RCE or DOE. In an embodiment, the process 670 may further comprise monitoring a performance of a chamber on an ongoing basis with virtual metrology based on the causal associations validated through the physical experimentation.

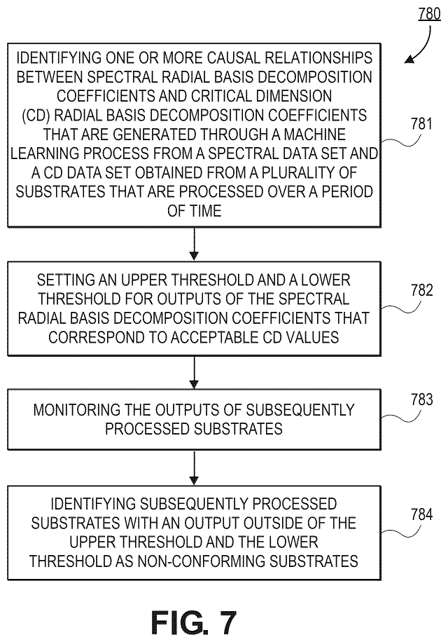

Referring now to FIG. 7 a flow diagram of a process 780 for implementing virtual metrology on processed substrates is shown, in accordance with an additional embodiment. In an embodiment, the process 780 may begin with operation 781, which comprises identifying one or more causal relationships between spectral radial basis decomposition coefficients and CD radial basis decomposition coefficients that are generated through a machine learning process from a spectral data set and a CD data set obtained from a plurality of substrates that are processed in a plurality of chambers over a period of time. In an embodiment, the one or more the causal relationships may comprises a relationship between a temporal trend (or any suitable trend resulting from a do-operation (e.g., a DOE and/or an RCE) of the decomposition coefficients (e.g., eigen values) of the spectral data and of a temporal trend (or any suitable trend resulting from a do-operation (e.g., a DOE and/or an RCE) of decomposition coefficients (e.g., eigen values) of the CD data. In an embodiment, the machine learning process may comprise extracting spectral features from the spectral data set and CD features from the CD data set, and implementing a radial basis decomposition process on the spectral features and the CD features to develop the spectral radial basis decomposition coefficients and the CD radial basis decomposition coefficients. In an embodiment, the feature extraction process comprises one or more of a SVD process, an ICA process, a PCA process, Fourier transforms, wavelet transforms, power spectral density, autoencoders, singular spectral analysis, filter banks, or the like. In an embodiment, the radial basis decomposition process may use of one or more of a Zernike function, a Bessel function, spherical harmonics, aspheric polynomials or an orthogonal function on a unit disk, such as Legendre, Legendre-Fourier, Chebyshev, Laguerre, Jacobi, or the like. The causal relationships between the one or more spectral radial basis decomposition coefficients and the one or more CD radial basis decomposition coefficients may be validated through physical experimentation, such as a do-operation (e.g., a DOE, a RCE, or the like). In an embodiment, the spectral data comprises IR reflectometry data or ellipsometry data.

In an embodiment, the process 780 may continue with operation 782, which comprises setting an upper threshold and a lower threshold for outputs of the spectral radial basis decomposition coefficients that correspond to acceptable CD values. The upper threshold and the lower threshold may be used in order to provide limits that indicate when a substrate is outside of specifications and is a non-conforming substrate.

In an embodiment, the process 780 may continue with operation 783, which comprises monitoring the outputs of subsequently processed substrates. For example, the subsequently processed substrates may be monitored with additional spectral metrology. Spectral metrology can be implemented faster and less intrusively than CD metrology or the like. As such, more substrates can be monitored during processing. Since there is a causal association developed between spectral metrology and CD values, simply running the spectral metrology is sufficient to determine the CD values.

In an embodiment, the process 780 may continue with operation 784, which comprises identifying subsequently processed substrates with an output outside of the upper threshold and the lower threshold as non-conforming substrates. In an embodiment, non-conforming substrates may undergo additional metrology. The additional metrology may be used to validate the non-conforming status of the substrate. Additionally, the additional metrology may be used to investigate the source of the non-conforming status, such as if maintenance needs to implemented on the chamber used to process the substrate, or to find out if one or more control knobs need to be adjusted to improve processing outcomes.

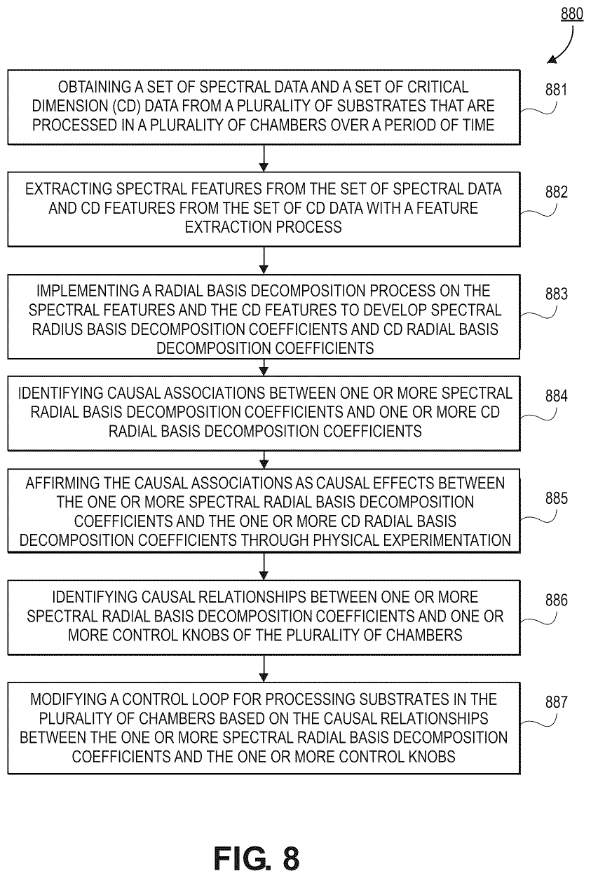

Referring now to FIG. 8, a process flow diagram of a process 880 for improving a control loop for a semiconductor processing process is shown, in accordance with an embodiment. In an embodiment, the process 880 may begin with operation 881, which comprises obtaining a set of spectral data and a set of CD data from a plurality of substrates that are processed in a plurality of chambers over a period of time. In an embodiment, the spectral data comprises any suitable type of spectral metrology measurement, such as IR reflectometry data or ellipsometry data. In an embodiment, the period of time may be one or more days, three or more days, or five or more days.

In an embodiment, the process 880 may continue with operation 882, which comprises extracting spectral features from the set of spectral data and CD features from the set of CD data with a feature extraction process. In an embodiment, the feature extraction process comprises one or more of a SVD process, an ICA process, a PCA process, Fourier transforms, wavelet transforms, power spectral density, autoencoders, singular spectral analysis, filter banks, or the like. In an embodiment, one or both of the spectral features or the CD features are modified through one or more of a transformation process, a regularization process, or a normalization process. In an embodiment, one or both of the spectral features and the CD features are used to build a within wafer feature map for each of the substrates processed in the plurality of chambers.

In an embodiment, the process 880 may continue with operation 883, which comprises implementing a radial basis decomposition process on the spectral features and the CD features to develop spectral radial basis decomposition coefficients and CD radial basis decomposition coefficients. In an embodiment, the radial basis decomposition process comprises the use of one or more of a Zernike function, a Bessel function, spherical harmonics, aspheric polynomials or an orthogonal function on a unit disk, such as Legendre, Legendre-Fourier, Chebyshev, Laguerre, Jacobi, or the like.

In an embodiment, the process 880 may continue with operation 884, which comprises identifying causal associations between one or more spectral radial basis decomposition coefficients and one or more CD radial basis decomposition coefficients.

In an embodiment, the process 880 may continue with operation 885, which comprises affirming causal associations as causal effects between the one or more spectral radial basis decomposition coefficients and the one or more CD radial basis decomposition coefficients through physical experimentation and/or observational data. For example, the causal effects between the one or more spectral radial basis decomposition coefficients and the one or more CD radial basis decomposition coefficients may be validated through physical experimentation, such as a do-operation (e.g., a RCE or DOE).

In an embodiment, the process 880 may continue with operation 886, which comprises identifying causal relationships between the one or more spectral radial basis functions and one or more control knobs of the plurality of chambers. In an embodiment, the one or more the causal associations may comprises a relationship between a temporal trend (or any suitable trend resulting from a DOE and/or an RCE) of coefficients (e.g., eigen values) of the spectral data (e.g., from the spectral radial basis function) and of a temporal trend (or any suitable trend resulting from a DOE and/or an RCE) of coefficients (e.g., eigen values) of the one or more control knobs. In an embodiment, the causal relationships and effects may be developed through the use of physical experimentation, such as sensitivity testing or the like. In an embodiment, the one or more control knobs comprise one or more of a RF power, an FRC ratio, an ESC temperature, a hardware component configuration, or the like.

In an embodiment, the process 880 may continue with operation 887, which comprises modifying a control loop for processing substrates in the plurality of chambers based on the causal relationships between the one or more spectral radial basis decomposition coefficients and the one or more control knobs. The modification to the control loop may be implemented manually or through an automated process.

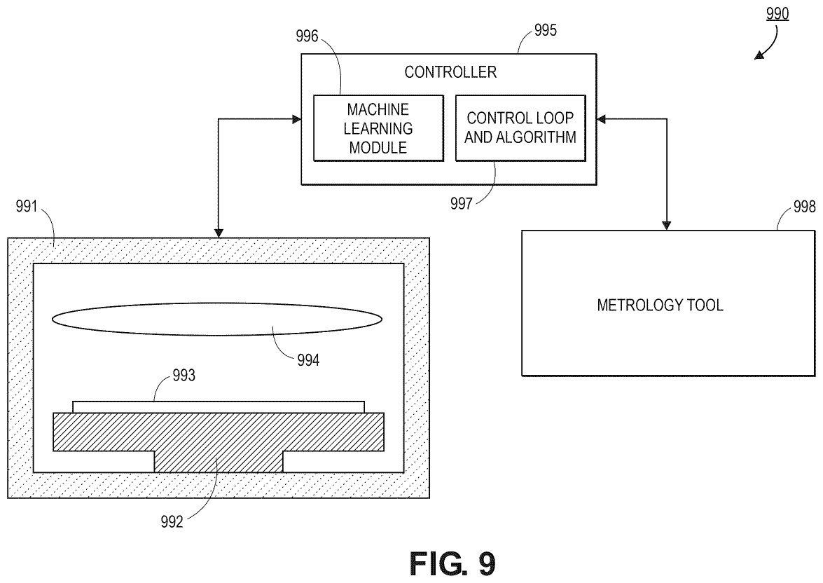

Referring now to FIG. 9, a schematic of a semiconductor processing system 990 is shown, in accordance with an embodiment. The system 990 may comprise one or more chambers 991 (though only one is shown for simplicity). A pedestal 992 may be provided in the chamber 991 to support a substrate 993. In some embodiments, the chamber 991 may be suitable for supporting a plasma 994. The chamber 991 may be any type of chamber for semiconductor processing, such as an etching chamber, a deposition chamber, an annealing chamber, or the like.

In an embodiment, the system 990 may also comprise a metrology tool 998. The metrology tool 998 may include any suitable type (or types) of metrology tool for monitoring properties of the processed substrate 993. For example, the metrology tool may be an IR reflectometry tool in some embodiments.

In an embodiment, the chamber 991 and the metrology tool 998 may be communicatively coupled to a controller 995. The controller 995 may comprise a machine learning module 996. The machine learning module 996 may obtain data from the chamber 991 and/or the metrology tool 998 in order to discover causal associations between datasets. For example, causal associations between two or more of metrology data, CD data, and/or sensor data may be determined by the machine learning module 996 through the use of any of the methodologies, processes, and/or methods described in greater detail herein. In an embodiment, the machine learning module 996 may be used to implement virtual metrology and/or sensing and/or to develop and/or refine a control loop and/or algorithm 997 that is used to process substrates 993 in the plurality of chambers. The control loop and/or algorithm 997 may be similar to any of those described in greater detail herein.

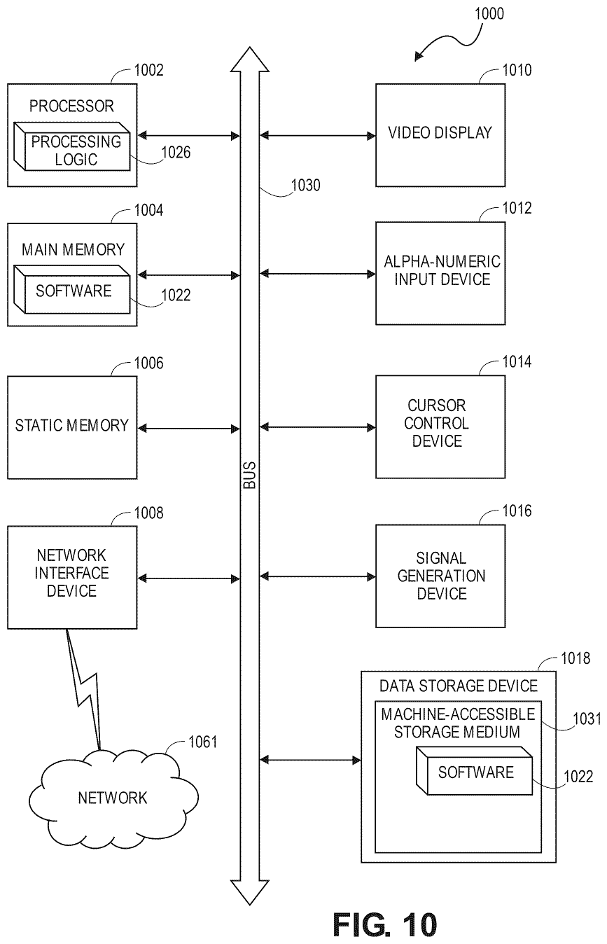

Referring now to FIG. 10, a block diagram of an exemplary computer system 1000 of a processing tool is illustrated in accordance with an embodiment. In an embodiment, computer system 1000 is coupled to and controls one or more semiconductor processing chambers using a control loop that is developed and/or refined through the use of a machine learning process.

Computer system 1000 may be connected (e.g., networked) to other machines in a Local Area Network (LAN), an intranet, an extranet, or the Internet. Computer system 1000 may operate in the capacity of a server or a client machine in a client-server network environment, or as a peer machine in a peer-to-peer (or distributed) network environment. Computer system 1000 may be a personal computer PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1000, the term “machine” shall also be taken to include any collection of machines (e.g., computers) that individually or jointly execute a set (or multiple sets) of instructions to perform any one or more of the methodologies described herein.

Computer system 1000 may include a computer program product, or software 1022, having a non-transitory machine-readable medium having stored thereon instructions, which may be used to program computer system 1000 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1000 includes a system processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

System processor 1002 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1002 may also be one or more special-purpose processing devices such as an application specific integrated circuit (ASIC), a field programmable gate array (FPGA), a digital signal system processor (DSP), network system processor, or the like. System processor 1002 is configured to execute the processing logic 1026 for performing the operations described herein.

The computer system 1000 may further include a system network interface device 1008 for communicating with other devices or machines. The computer system 1000 may also include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium 1031 (or more specifically a computer-readable storage medium) on which is stored one or more sets of instructions (e.g., software 1022) embodying any one or more of the methodologies or functions described herein. The software 1022 may also reside, completely or at least partially, within the main memory 1004 and/or within the system processor 1002 during execution thereof by the computer system 1000, the main memory 1004 and the system processor 1002 also constituting machine-readable storage media.

The software 1022 may further be transmitted or received over a network 1061 via the system network interface device 1008. In an embodiment, the network interface device 1008 may operate using microwave coupling, optical coupling, acoustic coupling, or inductive coupling.

While the machine-accessible storage medium 1031 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include a system for controlling one or more semiconductor processing chambers using a control loop that is developed and/or refined through the use of a machine learning process.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. A method, comprising:
obtaining a set of spectral data and a set of critical dimension (CD) data from a plurality of substrates;
extracting a spectral feature from the set of spectral data and a CD feature from the set of CD data with a feature extraction process;
implementing a first radial basis decomposition process on the spectral feature and a second radial basis decomposition process on the CD feature to develop a spectral radial basis decomposition coefficient and CD radial basis decomposition coefficient; and
identifying a causal relationship between the spectral radial basis decomposition coefficient and the CD radial basis decomposition coefficient based on a temporal trend.

2. The method of claim 1, wherein the feature extraction process comprises one or more of a singular value decomposition (SVD) process, an independent component analysis (ICA) process, a principal component analysis (PCA) process, Fourier transforms, wavelet transforms, power spectral density, autoencoders, singular spectral analysis or filter banks.

3. The method of claim 1, wherein the first radial basis decomposition process and/or the second radial basis decomposition process comprises one or more of a Zernike function, a Bessel function, spherical harmonics, aspheric polynomials or an orthogonal function on a unit disk, such as Legendre, Legendre-Fourier, Chebyshev, Laguerre, or Jacobi.

4. The method of claim 1, wherein one or both of the spectral feature or the CD feature are modified through one or more of a transformation process, a regularization process, or a normalization process.

5. The method of claim 1, wherein the spectral feature and the CD feature are used to build a within substrate feature map for each substrate processed in a chamber.

6. The method of claim 1, wherein the set of spectral data comprises infrared (IR) reflectometry data or ellipsometry data.

7. The method of claim 1, wherein the plurality of substrates are processed in a chamber over a period of time that is three or more days.

8. The method of claim 7, wherein the plurality of substrates are processed in a plurality of chambers.

9. The method of claim 1, further comprising:
validating the causal relationship between the spectral radial basis decomposition coefficient and the CD radial basis decomposition coefficient through physical experimentation and/or observational data.

10. The method of claim 9, wherein the physical experimentation comprises a randomized controlled experiment and/or a design of experiments (DOE).

11. The method of claim 1, wherein a plurality of spectral features are extracted from the set of spectral data, wherein a plurality of CD features are extracted from the set of CD data, wherein the first radial basis decomposition process for the plurality of spectral features and the second radial basis decomposition process for the plurality of CD features produces a plurality of spectral radial basis decomposition coefficients and a plurality of CD radial basis decomposition coefficients, and wherein a plurality of causal relationships are determined between one or more of the plurality of spectral radial basis decomposition coefficients and one or more of the plurality of CD radial basis decomposition coefficients.

12. A method, comprising:
identifying a causal relationship between a spectral radial basis decomposition coefficient and a critical dimension (CD) radial basis decomposition coefficient, wherein the causal relationship comprises an association between a first temporal trend of the spectral radial basis decomposition coefficient and a second temporal trend of the CD radial basis decomposition coefficient, wherein the causal relationship is generated through a machine learning process that is applied to a spectral data set and a CD data set that are obtained from a plurality of substrates;
setting an upper threshold and a lower threshold for the spectral radial basis decomposition coefficient that corresponds to acceptable CD values;
monitoring spectral radial basis decomposition coefficient outputs of subsequently processed substrates; and
identifying one or more subsequently processed substrates with a spectral radial basis decomposition coefficient output that is outside of the upper threshold and the lower threshold as a non-conforming substrate.

13. The method of claim 12, further comprising:
performing additional metrology on the non-conforming substrate.

14. The method of claim 12, wherein the machine learning process comprises:
extracting a spectral feature from the spectral data set and a CD feature from the CD data set; and
implementing a radial basis decomposition process on the spectral feature and the CD feature to develop the spectral radial basis decomposition coefficient and the CD radial basis decomposition coefficient.

15. The method of claim 14, wherein extracting the spectral feature comprises one or more of a singular value decomposition (SVD) process, an independent component analysis (ICA) process, a principal component analysis (PCA) process Fourier transforms, wavelet transforms, power spectral density, autoencoders, singular spectral analysis or filter banks, and wherein the radial basis decomposition process comprises uses of one or more of a Zernike function, a Bessel function, spherical harmonics, aspheric polynomials or an orthogonal function on a unit disk, such as Legendre, Legendre-Fourier, Chebyshev, Laguerre, or Jacobi.

16. The method of claim 12, wherein the causal relationship between the spectral radial basis decomposition coefficient and the CD radial basis decomposition coefficient is validated through physical experimentation.

17. The method of claim 12, wherein a plurality of causal relationships are identified between one or more of a plurality of spectral radial basis decomposition coefficients and one or more of a plurality of CD radial basis decomposition coefficients, wherein the plurality of causal relationships comprise one or more relationships between one or more temporal trends of the plurality of spectral radial basis decomposition coefficients and the one or more temporal trends of the plurality of CD radial basis decomposition coefficients.

18. The method of claim 12, wherein the plurality of substrates are processed in a plurality of chambers.

19. A method, comprising:
obtaining a set of spectral data and a set of critical dimension (CD) data from a plurality of substrates;
extracting a spectral feature from the set of spectral data with a first feature extraction process and a CD feature from the set of CD data with a second feature extraction process;
implementing a first radial basis decomposition process on the spectral feature and a second radial basis decomposition process on the CD feature to develop a spectral radial basis decomposition coefficient and a CD radial basis decomposition coefficient;
identifying a causal association between the spectral radial basis decomposition coefficient and the CD radial basis decomposition coefficient;
affirming the causal association as a causal effect between the spectral radial basis decomposition coefficient and the CD radial basis decomposition coefficient through physical experimentation and/or observational data;
identifying a causal relationship between the spectral radial basis decomposition coefficient and a control knob of a chamber, wherein the causal relationship comprises a relationship between a temporal trend of the spectral radial basis decomposition coefficient and a temporal trend of the control knob; and
developing and/or modifying a control loop for processing substrates in the chamber based on the causal relationship between the spectral radial basis decomposition coefficient and the control knob.

20. The method of claim 19, wherein a plurality of spectral features are extracted from the set of spectral data, wherein a plurality of CD features are extracted from the set of CD data, wherein the spectral radial basis decomposition coefficient of the plurality of spectral features and the CD radial basis decomposition coefficient of the plurality of CD features produces a plurality of spectral radial basis decomposition coefficients and a plurality of CD radial basis decomposition coefficients, wherein a plurality of causal relationships are provided between one or more of the plurality of spectral radial basis decomposition coefficients and one or more of the plurality of CD radial basis decomposition coefficients, and wherein the plurality of substrates are processed in a plurality of chambers.
